(19) United States
(12) Patent Application Publication
(10) Pub. No.: US 2024/0178638 A1
(43) Pub. Date: May 30, 2024

(54) SEMICONDUCTOR LASER DIODE ARRAY AND THE METHOD FOR MANUFACTURING A TWO-DIMENSIONAL SEMICONDUCTOR LASER DIODE ARRAY

(71) Applicants: Topgan Sp. z o.o., Warszawa (PL); Instytut Wysokich Cisnien Polskiej Akademii Nauk, Warszawa (PL)

(72) Inventors: Anna KAFAR, Gdynia (PL); Krzysztof GIBASIEWICZ, Warszawa (PL); Jacek KACPERSKI, Warszawa (PL); Kiran SABA, Shorkot (PK); Szymon STANCZYK, Gdynia (PL); Piotr PERLIN, Warszawa (PL)

(73) Assignees: Topgan Sp. z o.o., Warszawa (PL); Instytut Wysokich Cisnien Polskiej Akademii Nauk, Warszawa (PL)

(21) Appl. No.: 18/282,804

(22) PCT Filed: Mar. 21, 2022
(86) PCT No.: PCT/PL2022/050016

§ 371 Date: Sep. 19, 2023

(30) Foreign Application Priority Data
Mar. 19, 2021 (PL) P.437357

(51) Int. Cl. H01S 5/42; H01S 5/02; H01S 5/02255; H01S 5/20; H01S 5/34; H01S 5/343; H01S 5/40

(52) U.S. Cl. CPC H01S 5/42; H01S 5/0206; H01S 5/02255; H01S 5/2009; H01S 5/2081; H01S 5/3408; H01S 5/34333; H01S 5/4075

(57) ABSTRACT

The invention relates to a method for manufacturing a two-dimensional laser diode array comprising preparing a structured gallium nitride bulk substrate, a lower cladding layer, a lower light guide layer, a light-emitting layer, electron blocking layers, an upper light guide layer, an upper cladding layer, a subcontact layer, and includes forming, in GaN substrate (1) with thickness of at least 200 μm, light beam deflectors (15) by applying photoresist on the GaN substrate (1), irradiating it, developing it, and subsequently etching the applied layer in order to obtain the light beam deflectors (15). The invention relates also to a two-dimensional laser diode array manufactured using the method according to the invention.

The present invention relates to a method for manufacturing a two-dimensional array of edge-emitting semiconductor laser diodes based on an AlInGaN alloy and to a array manufactured using said method.

Semiconductor lasers have a number of advantages such as: small dimensions, a possibility of engineering the wavelength of the emitted light, or a possibility of manufacturing monolithic emitter assemblies—arrays. The arrays allow expanding the application of devices by obtaining a monolithic system that emits higher optical powers, a possibility of uniform illumination of a larger area by means of multiple beams, or a monolithic system with multiple emitters operating independently (addressable arrays).

Laser diodes are devices that require advanced engineering of semiconductor alloys both in terms of electrical and optical properties. The basic structural elements of a laser include: the active region comprising a light generating and amplifying medium, a waveguide allowing localising light in a selected area by means of layers characterised by a different refractive index, and a resonant cavity proving positive feedback, that is, returning the amplified light to the waveguide for further amplification. Laser diodes are manufactured in two basic configurations: edge-emitting or surface-emitting. Typical properties and manufacturing methods for these two types of devices have been extensively described in the book L.A. Coldren, S. W. Corzine, “Diode Lasers and Photonic Integrated Circuits” Opt. Eng. 36(2), 616-617 (1997). The main difference between these types of devices is their geometry: edge-emitting diodes have a resonant cavity oriented in the quantum well plane, and the light is emitted from the edge of the structure, whereas the surface-emitting diodes have a resonant cavity oriented perpendicularly to the quantum wells, and the emission occurs from the surface of the structure. The change in geometry affects a number of aspects, such as manufacturing methods, technological challenges, or parameters of the obtained light beam.

In case of edge emitters, an advantage of the cavity orientation with respect to the quantum well plane is high amplification resulting from the fact that the amplifying medium (quantum well) is present along the entire length of the resonant cavity. At the same time, the optical mode has a larger cross-section than the quantum well. The light is emitted from the edge of the crystal from the area that has a surface area equal to the cross-section of the optical mode, which depends on the parameters of the manufactured waveguide. This configuration allows, among others, obtaining high optical powers due to the high amplification (Erbert G., Barwolff A., Sebastian J., Tomm J. (2000) High-Power Broad-Area Diode Lasers and Laser Bars. In: Diehl R. (eds) High-Power Diode Lasers. Topics in Applied Physics, vol. 78. Springer, Berlin, Heidelberg). However, it has a significant limitation from the perspective of laser arrays: in order to create a resonant cavity, it is necessary to divide the crystal along the cleavage planes. As a result, manufacturing laser arrays is possible only in a form of laser bars—one-dimensional arrays.

In case of surface-emitting emitters, the optical mode is oriented perpendicularly to the plane of the active region, therefore they provide much lower optical amplification. At the same time, this geometry requires more complicated, compared with edge-emitting lasers, manufacturing of the resonant cavity. This is done by manufacturing Bragg mirrors that are monolithic (based on an epitaxial structure) or embedded on an epitaxial structure. Due to the low amplification, said mirrors must be characterised by high reflectivity that is close to one (A. Karim, S. Bjorlin, J. Piprek, J. E. Bowers, “Long-wavelength vertical-cavity lasers and amplifiers”, Selected Topics in Quantum Electronics IEEE Journal of, vol. 6, no. 6, pp. 1244-1253, 2000), which poses a significant technological challenge. An additional challenge is producing a waveguide (a refractive index contrast) perpendicularly in relation to the epitaxial layers, while simultaneously providing current injection to the active region (D. L. Huffaker, D. G. Deppe, K. Kumar, Appl. Phys. Lett. vol. 65, pp. 97, 1994). Although surface-emitting lasers typically have lower optical powers than edge-emitting lasers, their advantages include, among others, a possibility of manufacturing two-dimensional emitter arrays.

There are reports about laser arrays manufactured in edge-emitting laser geometry but with additionally etched mirrors/deflectors, which enable surface emission—this solution was demonstrated for the arsenide or phosphide material group (T. H. Windhorn and W. D. Goodhue, Appl. Phys. Lett. 48, p. 1675, 1986; J. J. Yang, M. Sergant, M. Jansen, S. S. Ou, L. Eaton, W. W. Simmons, Appl. Phys. Lett. 49, p.1138, 1986; Z. L. Liau and J. N. Walpole, Appl. Phys. Lett. 50, p. 528, 1987; J. P. Donnelly, W. D. Goodhue, T. H. Windhorn, R. J. Bailey, S. A. Lambert, Appl. Phys. Lett. 51, p. 1138, 1987; J.H. Kim, R. J. Lang, A. Larsson, L. P. Lee, A. A. Narayanan, Appl. Phys. Lett. 57, p. 2048, 1990). However, said devices have not been commercialised, probably because of a small increase of the optical power with an increased number of emitters in the array. This problem may be caused by too large losses with the change of laser beam direction (deflector reflection), as well as high level of self-heating of this type of laser arrays (high density of emitters with insufficiently effective heat dissipation).

(Al,In,Ga)N nitride semiconductors material group, which the present invention relates to, allows obtaining semiconductor emitters in preferably wide wavelength range, having higher photon energy than other popular groups: arsenides or phosphides. Currently, edge-emitting laser diodes in range of about 375 nm-545 nm are commercially available, while it is theoretically possible to widen this range in the direction of both short waves and long waves.

Classic technology of nitride laser manufacturing has been described, among others, in the publication by S. Nakamura, “InGaN/GaN/AlGaN-based laser diodes grown on epitaxially laterally overgrown GaN,” J. Mater. Res. 14, 2716 (1999) and in the patent description U.S. Pat. No. 6,838,693 B2. As a substrate, mono-crystalline gallium nitride with a thickness of 50 to 200 μm is used. The surface of gallium nitride is prepared for epitaxial growth by mechano-chemical polishing in order to obtain an atomically smooth surface. By polishing the surface at a selected angle to the crystallographic planes of the crystal, atomic steps are obtained. Growth of structures on such a substrate can be carried out both by the method of epitaxy from metal-organic compounds and by the method of molecular beam epitaxy. The cladding layers are made of gallium-aluminium nitride AlₓGa₁₋ₓN, for which x is comprised in range of 0.05 to 0.12 and with a thickness of 0.5 μm to 5 μm. The lower cladding layer is doped with silicone on a level of 5×10¹⁸ cm⁻³. The upper cladding layer is typically doped with magnesium on a level of 5×10¹⁸ cm⁻³ to 1×10¹⁹ cm⁻³. The light guide layers are typically made of gallium nitride with a thickness of 0.05 μm to 0.15 μm. The lower light guide layer can be doped with silicone and the upper light guide layer can be doped with magnesium. Both light guide layers can also be undoped. The electrode blocking layers, in case of diodes emitting in range of 390-550 nm, are made of AlₓGa₁₋ₓN, for which x is comprised in range of 0 to 0.2. The layer constituting the light-generating active region can consist of a single InₓGa₁₋ₓN quantum well, for which x is comprised in range of 0 to 0.3, and has a thickness of 2 nm do 10 nm, as well as a few quantum wells with an analogical structure, separated by barriers of GaN or InₓGa₁₋ₓN with In content lower than that of the quantum well. As the final layer, above the upper cladding layer, a subcontact layer is obtained, highly doped with magnesium on a level of 5×10¹⁹ cm⁻³ to 1×10²⁰ cm⁻³.

The light guiding is achieved by etching selected regions of the epitaxial structure to a depth not exceeding the boundary between the upper cladding and the upper light guide layer. The etching region is chosen such that the remaining material forms a light guide perpendicular to the exit window of the light guide (the cleavage planes of the crystal). From the top side of the instrument, electric power supply is provided only by the top surface of the formed mesa (ridge) by means of the deposited contact layer made of gold. The regions outside the surface of the mesa are electrically insulated by means of a dielectric layer made, for example, of SiO₂ or SiN. In order to form a resonant cavity, the crystal is cleaved along the crystal easy cleavage planes, and the obtained atomically smooth edges form Fabry-Perot type mirrors of the resonant cavity. In order to achieve high cleaving precision and thus the quality of mirrors, it is common to polish the processed crystal on its bottom side, which leads to thinning it to a thickness of 150 μm. Next, another cleaving in the direction perpendicular to the direction of mirrors is performed, allowing division into individual laser chips.

One of the fundamental parameters determining the quality of laser diodes is the maximum optical power obtained. In case of majority of devices based on nitrides, the obtained limit results either from the efficiency of carrier injection into the quantum well or from the thermal escape of the carriers from the quantum well. Thermal escape depends directly on the thermal properties of the structure. A good method of improving these properties is improving heat dissipation from the active region.

In case of the nitride material group, heat dissipation to the substrate plays a major role, because of its high thermal conductivity. However, the thermal properties of GaN bulk substrate are significantly deteriorated in the process of crystal thinning, allowing forming laser mirrors by cleaving the crystal along its cleavage planes. Reducing the volume of the crystal directly causes the decrease of its heat capacity.

Another technological problem of the nitride material group is a mismatch of lattice parameters of GaN, AlN, and InN binary crystals. For this reason, it is technologically difficult to manufacture a laser, which requires light guide layers (core and cladding) having significantly different compositions. Whereas, in case of surface-emitting diodes, an even more complicated Bragg mirror structure is required. There are reports in literature relating to surface-emitting nitride laser diodes (T. Hamaguchi, H. Nakajima, N. Fuutagawa, Appl. Sci. 9(4), p. 733, 2019; T.-C. Chang, E. Hashemi, K.-B. Hong, J. Bengtsson, J. Gustaysson, Å. Haglund, and T.-C. Lu, ACS Photonics 7 (4), p. 861, 2020), but it is a very demanding topic, which does not yet have a developed technology and is far from commercialisation. However, from the perspective of wide application of nitride lasers, e.g. for white light generation using excitation of phosphors, obtaining two-dimensional laser diode arrays is highly desired.

Manufacturing two-dimensional laser diode arrays directly based on technologies reported so far (Kim et al., Appl. Phys. Lett. 57, p. 2048 (1990), Donnely et al., Appl. Phys. Lett. 51, 1138 (1987)) imposes strong geometrical limitations. Because the height of the deflector and the semiconductor structure is the same, and the total reflection of the light beam by the deflector is possible only if the etching depth satisfies the relationship: D=H ctg(θ). Where H is a depth at which the centre of the optical mode is located on the mirror in relation to the top edge of the crystal, while θ is the half-angle of light beam divergence in the vertical direction (fast axis). Taking into account the presence of errors in manufacturing of devices, it is preferred for the value D to be less than the calculated limit. In case of a nitride structure, such manufacturing scheme is significantly more difficult, due to a limited thickness of layers above the active region. In typical (Al,In)GaN laser structures, there is a problem of degradation of InGaN wells while growing waveguide cladding requiring an AIGaN type material with significantly higher optimal growth temperatures. Another limitation is low electrical conductivity of p-type layers, resulting from the technologically demanding doping process of these layers. As a result, these layers have a typical thickness no greater than 2 μm. Taking into account θ values of the order of 35°, which are typical for devices based on nitrides, because of a low H value, the etching depth and the deflector width should be less than 2 μm. Taking into account the precision error of photolithographic processes of the order of 1 μm, there is a high probability of manufacturing a system with high losses, in which the light is not fully reflected by the deflector.

Unexpectedly, technical problems listed above have been solved by the present invention.

The invention relates to a method for manufacturing a two-dimensional laser diode array comprising preparing:
a) a structured gallium nitride bulk substrate,
b) a lower cladding layer with n-type electrical conductivity,
c) a lower light guide layer with n-type electrical conductivity,
d) a light-emitting layer,
e) an electron blocking layer with p-type electrical conductivity,
f) an upper light guide layer,
g) an upper cladding layer with p-type electrical conductivity,
h) a subcontact layer with p-type electrical conductivity,
   with etched ridges defining the laser waveguides and etched mirrors constituting the resonant cavity, characterised in that the method, in step (a), includes forming, in GaN bulk substrate with a thickness of at least 200 μm, light beam deflectors by applying a positive photoresist layer, irradiating it with a spatially variable dose of light, developing and subsequently dry etching the applied layer in order to obtain the light beam deflectors, wherein the light beam deflectors comprise two planes, namely a parallel deflector plane in relation to the GaN substrate and an oblique deflector plane tilted at an angle in range of 40°-50° in relation to the surface of the GaN substrate, wherein dry etching is carried out before epitaxy of the lower cladding layer with n-type electrical conductivity, and the parallel deflector plane is located higher than the subcontact layer applied in step (h) by at least 0.5 μm.

Preferably, according to the invention, a two-dimensional laser diode array is obtained, satisfying the relation defined by the equation,

$$\frac{{H}_{V} - {H}_{QW} + {D}_{V}}{1 - Tan ( {α}_{1 / 2} )} \cdot Tan ( {α}_{1 / 2} ) + {H}_{V} - {H}_{QW} < 0.095 {H}_{D}$$

wherein,
H_{V} is the etching depth of the vertical mirror,
H_{OW} is the height difference between the top plane of the subcontact layer and the quantum well plane,
D_{V} is the distance between the vertical mirror and the bottom edge of the oblique deflector plane, tilted at an angle of 45° in relation to the GaN substrate,
H_{D} is the height of the oblique deflector plane, tilted at an angle of 45° in relation to the GaN substrate.

Preferably, according to the invention, dry etching is carried out by means of reactive ion etching method using argon-chlorine plasma.

Preferably, according to the invention, after dry etching of the applied photoresist layer, light beam deflectors with an inclination angle of the oblique plane of deflectors in relation to the surface of the GaN substrate equal to 40° are obtained.

Preferably, according to the invention, after epitaxial growth of the subcontact layer, light beam deflectors with an inclination angle of the oblique plane of deflectors in relation to the surface of the GaN substrate preferably equal to 45° are obtained.

Preferably, according to the invention, the parallel planes of deflectors and the oblique planes of deflectors are coated with a layer with a high reflection coefficient.

Preferably, according to the invention, the layer with a high reflection coefficient is formed by alternating deposition of SiO₂ and Ta₂O₅ using electron-beam vacuum evaporation method.

The invention relates also to a two-dimensional laser diode array based on an AlInGaN alloy, manufactured using the method according to the invention, comprising sequentially a structured gallium nitride bulk substrate, a lower cladding layer with n-type electrical conductivity, a lower light guide layer with n-type electrical conductivity, a light-emitting layer, an electron blocking layer with p-type electrical conductivity, an upper light guide layer, an upper cladding layer with p-type electrical conductivity, and a subcontact layer with p-type electrical conductivity, with etched ridges defining waveguides of the laser diodes and etched mirrors forming the resonant cavity, characterised in that the GaN substrate has a thickness of at least 200 μm, and the laser diodes are arranged in a rectangular lattice, wherein each diode comprises light beam deflectors configured to change the direction of emitted light beams from parallel to perpendicular in relation to the plane defined by the layer constituting the light generating active region, wherein the light beam deflectors comprise two planes, namely a parallel deflector plane in relation to the GaN substrate and an oblique deflector plane tilted at an angle of 40°-50° in relation to the surface of the GaN substrate, wherein the parallel plane of deflectors is located higher than the subcontact layer by at least 0.5 μm.

Preferably, according to the invention, the two-dimensional array satisfies the relation defined by the equation,

$$\frac{{H}_{V} - {H}_{QW} + {D}_{V}}{1 - Tan ( {α}_{1 / 2} )} \cdot Tan ( {α}_{1 / 2} ) + {H}_{V} - {H}_{QW} < 0.95 {H}_{D}$$

wherein,
H_{V} is the etching depth of the vertical mirror,
H_{OW} is the height difference between the top plane of the subcontact layer and the quantum well plane,
D_{V} is the distance between the vertical mirror and the bottom edge of the oblique deflector plane, tilted at an angle of 45° in relation to the GaN substrate,
H_{D} is the height of the oblique deflector plane, tilted at an angle of 45° in relation to the GaN substrate.

Preferably, according to the invention, the oblique deflector planes after dry etching, are tilted at an angle of 40° in relation to the surface of the GaN substrate.

Preferably, according to the invention, the oblique deflector planes, after epitaxial growth of the subcontact layer, are tilted at an angle of 45° in relation to the surface of the GaN substrate.

Preferably, according to the invention, the parallel planes of deflectors and the oblique planes of deflectors are coated with a layer with a high reflection coefficient.

Preferably, according to the invention, the layer with a high reflection coefficient is constituted by a layer of SiO₂ and Ta₂O₅.

Preferably, according to the invention, the distance between the parallel planes, defined by the centre of the active region and the plane intersecting the deflector in the middle of its height, is comprised in range of +/−250 nm.

Preferably, according to the invention, the total thickness of the laser diode array structure measured from the bottom plane of the GaN substrate to the parallel plane of deflectors is comprised in range of 200 to 800 μm.

Preferably, according to the invention, the distance between the vertical mirror of the laser diode and the intersection of the extension of the waveguide axis of the laser diode with the oblique deflector plane is comprised in range of 2.5 do 7.5 μm.

The laser diode/emitter array is made on a GaN bulk substrate, on which epitaxial structure growth has been carried out. The lateral optical mode confinement is defined by etching of the ridge waveguide. The current path is defined by the opening in a dielectric insulation layer. The opening is placed at the top of ridge waveguide where later the top electrical contact has been deposited. The resonant cavity is defined by vertical mirrors, and the emitted light beam has been oriented by reflection from the deflectors. The reflection coefficient of the reflector surfaces has been increasing using coating.

The first step in manufacturing of arrays according to the invention, different from classic technology, is fabricating the structured GaN bulk substrate. The purpose of this step is obtaining oblique planes tilted in relation to the substrate surface at an angle in range of 30°-60° adjacently to the future ends of the laser waveguide. The planes should be oriented perpendicularly to the future waveguide and cause a change of height H on the crystal surface at least 1.5 times greater than the thickness of future epitaxial layers. From the perspective of the principle of operation of the device, there is no upper limit of the height of the manufactured structure, however in most cases it is limited by the geometry of the sample, among others, by the distance between emitters.

Manufacturing said layers is possible by means of, but with not limited to, a process based on photolithography and etching. Both multilevel and binary photolithography technology can serve to provide a photoresist layer with variable thickness. Maximum thickness of the photoresist defines the height H, but is not necessarily equal to it. This step is carried out using positive photoresist. Next, dry etching is performed by means of reactive ion etching method using argon-chlorine plasma. The proper selection of etching parameters allows structuring the surface of the GaN substrate to reflect the shape of the photoresist. The inclination angle of the oblique plane in range of 30°-60° should be chosen such that, at the end of all technological processes that can modify the GaN surface, a surface with an inclination in range of 44° to 46° is obtained. On a surface prepared in this manner, epitaxial growth is carried out, according to the conventional technology of nitride lasers.

After the epitaxial growth, conventional steps of manufacturing of laser diodes are carried out, allowing forming a ridge defining the waveguide of the devices, the electrical contact from the p-type side, and the insulation of the areas which are not intended to be electrically pumped. For the operation of laser diodes according to the invention, it is required for the ridges (waveguides) to be located on the areas of the substrate with a lower thickness, wherein the ends of the waveguide have to be located near the bottom edge of the oblique plane inclined at an angle of 45°, in a distance not exceeding half of the height change caused by this plane, while the direction of the waveguide should be as close as possible to the direction perpendicular to the inclined plane. Manufacturing details, such as the material used for electrical insulation of the mesa or the shape of the top contact field, should be chosen so as not to disrupt the later manufacturing steps underlying the invention.

In the next step, photolithography is carried out, allowing forming vertical edges of the crystal, defining the resonant cavity of laser diodes. Such etching simultaneously lowers the inclination of the plane. The etching depth should be chosen in such a way, so that the inclined plane being lowered can act as a laser beam deflector. That is, so that the whole light beam emitted from the etched vertical edge of the crystal can fit on the reflective plane. To this end, the etching depth is determined such that the parallel plane of deflectors, in relation to the GaN substrate, is located higher than the top plane of the subcontact layer by at least 0.5 μm. The position of the etching edge, and thus the mirrors of the laser diode, should be chosen to intersect the waveguide, thus forming a smooth mirror. The position of etching axis in relation to the edge of the plane depends on details of the geometry of this area and should be chosen to minimise the light dissipation losses of the system and it is usually mostly preferred to form it as close to the bottom edge of the deflector as possible. If the etching axis is located too far from the inclined plane, the system geometry changes and the entire light beam is not reflected by the deflector. Mirrors of the laser diode formed this way are subjected to wet etching, which is intended to smooth them after dry etching. The crystal is coated with a photoresist exposing only the vertical edges of the crystal constituting the mirrors of the resonant cavity. Then, wet etching is carried out by means of tetramethylammonium hydroxide (TMAH), the rate of which depends on the crystallographic directions of the structure, and exposes the mirror, improving its orientation in relation to the surface of the active region and enhancing its smoothness. The etching can be carried out both at room temperature and at an elevated temperature. After the wet etching process, the photoresist coating the structure is removed.

In order to increase the efficiency of operation of the device, it is possible to coat both deflector planes with a layer increasing the reflection coefficient of the deflector surfaces. This procedure is possible to be carried out both by means of dielectric (Bragg mirrors) and metallic layers. In typical scheme of this step of the process, the first step is to carry out photolithography defining the areas that are intended to be coated with a reflection enhancing layer, next the layers are deposited, and in the last step the lift-off process is performed, that is, removing the photoresist along with the material deposited on it. The areas covered with additional layers should be chosen in a way that does not lead to deterioration of parameters of the device, for example by short-circuiting the junction of the structure in case of depositing metal on the area of the vertical etched mirror.

The invention relates to a method for manufacturing a laser diode array and to the edge-emitting laser diode array provided with deflectors allowing directing the emitted light perpendicularly to the resonant cavity. This invention enables enriching the current technology of manufacturing of nitride edge-emitting laser diodes, so that it is possible to obtain two-dimensional arrays. High efficiency of conversion of the direction of light is achieved by a novel method of manufacturing of the deflectors with a height greater than the laser structure. At the same time, using thick gallium nitride substrate with high thermal conductivity and large surface area provides good heat dissipation, which results in an increase of efficiency of light generation in the active region and allows powering the devices with a higher current, which increases the maximum optical power of the device.

The presented scheme of array manufacturing can also be applied to superluminescent diodes having an epitaxial structure analogical to that of laser diodes. The basis of operation of the superluminescent diodes is manufacturing a system, in which, despite high density of photons and carriers leading to high amplification, lasing does not occur. Such devices have a waveguide, similarly to the lasers, but at least one of the ends of their waveguides has a low feedback, typically achieved by a low reflection coefficient. In the presented process, it is possible to manufacture the superluminescent diodes easily be etching the ends of the waveguide non-perpendicularly to the direction of the waveguide axis or non-perpendicularly to the plane of the active region.

In addition, an advantageous feature of the present invention is a possibility of manipulating the shape of the substrate without changing the parameters of the devices, e.g. the length of the laser waveguide, which parameter affects a number of optoelectric parameters.

The method according to the invention in the embodiment and the object of the invention in the embodiment have been described in more detail with reference to the drawing, on which

FIG. 1 shows the traditional technology of nitride laser manufacturing,

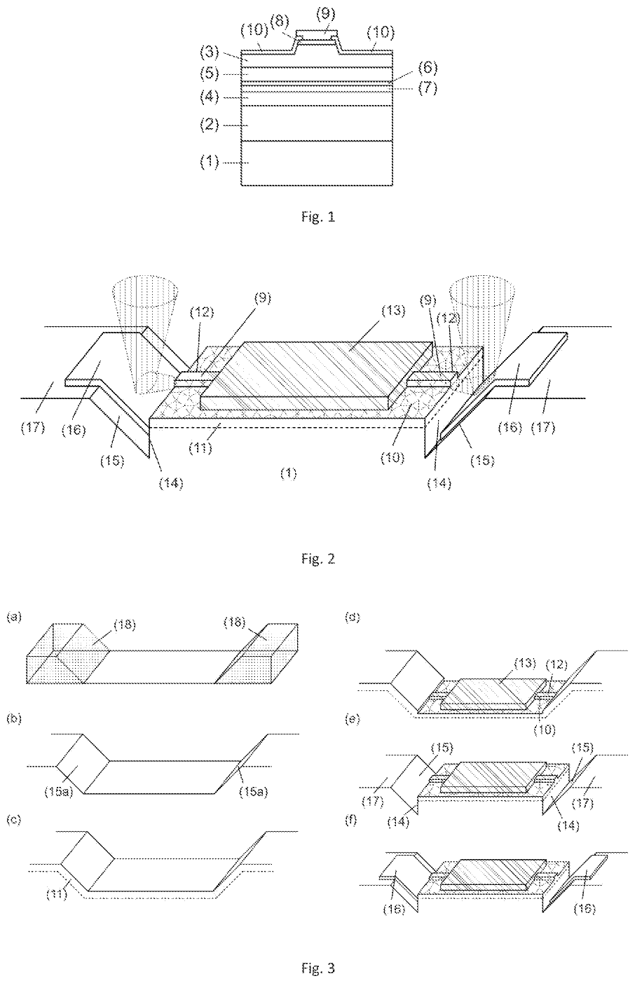

FIG. 2 shows a structural diagram of a laser with emission perpendicular to the direction of the resonant cavity,

FIG. 3 shows a diagram of subsequent steps of manufacturing of devices, wherein (a) shows the formation of a photoresist layer, (b) shows the formation of etched planes, (c) shows the epitaxial growth, (d) shows a diagram of a processed structure of a laser diode, (e) shows the array structure after etching of the vertical mirrors, (f) shows a diagram of coating the deflector planes with layers increasing the reflection coefficient of the deflector surface,

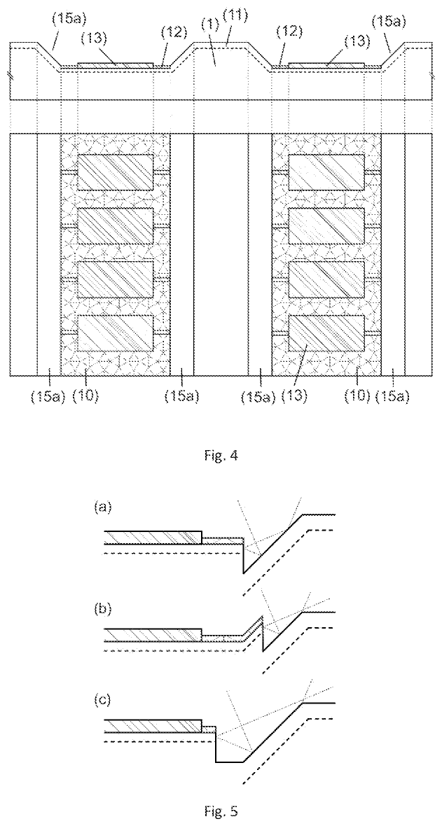

FIG. 4 shows an exemplary configuration of a laser diode array comprising eight emitters,

FIG. 5 shows the impact of position of the axis of the vertical etching in relation to the laser waveguide and the deflector on the efficiency of the change of the light beam direction, wherein (a) shows the ideal situation, (b) shows losses caused by the etching axis being too far away towards the deflector, (c) shows losses caused by the etching axis being too far away towards the laser,

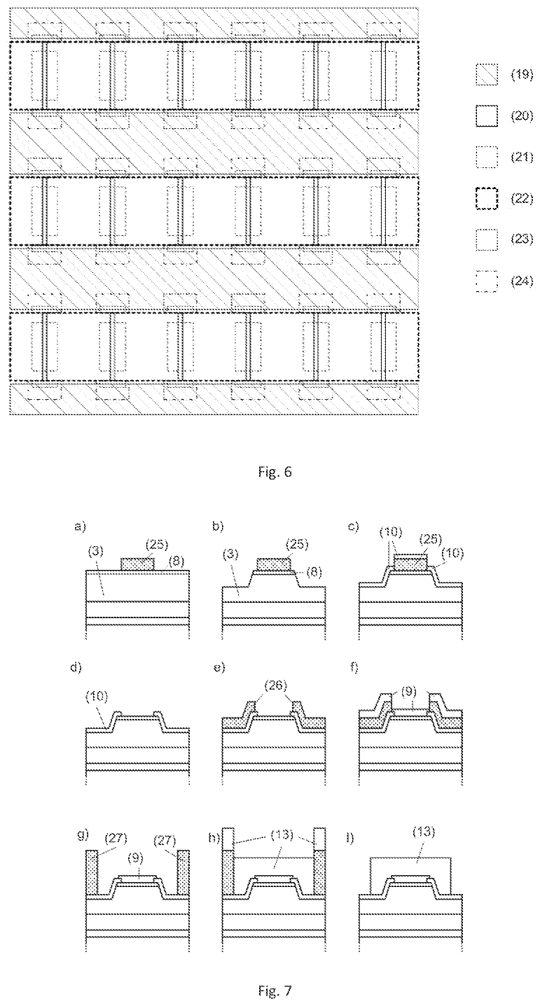

FIG. 6 shows an exemplary set of photolithography patterns for manufacturing laser diode arrays,

FIG. 7 shows subsequent steps of manufacturing of devices according to traditional methods of semiconductor laser manufacturing,

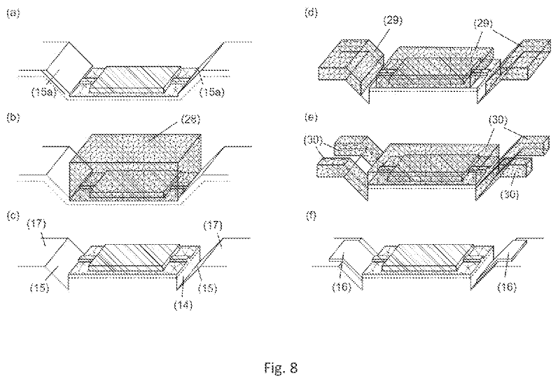

FIG. 8 shows the detailed steps of manufacturing of devices after completing the traditional steps of laser manufacturing: (a) an area of a single processed laser, (b) applying the resist defining the edge of vertical etching, (c) the laser after etching the vertical mirrors, (d) applying the resist exposing only the vertical mirrors in order to smooth their surface by wet etching, (e) applying the resist exposing the fields in order to embed the dielectric layers having high reflection, (f) finished device with layers having high reflection.

### EXAMPLE 1

The first embodiment of the present invention is a method for manufacturing a two-dimensional laser diode array with a square, uniform profile of the generated light, comprised of eighteen diodes/emitters. The array has been manufactured on a GaN substrate 1 obtained from high-pressure growth. In the first step of manufacturing such a array, the GaN substrate 1 has been formed by means of growth from a solution of nitrogen in gallium under pressure of 1000 MPa and at temperature of 1500° C. The resulting crystal was cleaved and polished so that it formed a flat-parallel wafer with typical thickness of 200 μm and dimensions of 12 mm×14 mm. The gallium polarity surface of this crystal, after proper mechano-chemical polishing, had atomic smoothness, which was manifested though atomic degrees in the Atomic Force Microscope image. The surface of the crystal was oriented 0.5° in relation to the direction of the crystallographic axis c of the hexagonal GaN structure (wurtzite).

Next, a 6 μm thick layer of positive photoresist 18 was deposited on the substrate. The layer has been irradiated by means of a “laser writer” device with a light source in a form of a laser with emission wavelength of 405 nm. The irradiation consisted of scanning the surface of the photoresist 18 with a light beam, wherein the light intensity changed non-gradually (binary photolithography) according to the design of the planes defining the future deflector planes 15a and 17. In this example, an irradiation pattern 19 was used, allowing forming, on the GaN substrate 1, a series of planes 15a with alternating inclination close to 45° in relation to the crystal surface in the crystallographic direction M. The oblique deflector planes 15a had a width of 5 μm, a length of 12 mm, and the spacing between them (the distance between the lowest points of adjacent planes) was equal to 1000 μm.

The substrate 1 with formed photoresist 18 was subjected to a dry etching process by means of reactive ion etching method using argon-chlorine plasma. The etching time was 17.5 minutes. The process allowed the shape of the photoresist 18 to be transferred to the bulk GaN substrate 1, forming both planes 15a and 17. Due to a small difference in the etching rate, while the height of the photoresist 18 decreased by 5 μm, the inclination angle of the oblique deflector planes 15a was also decreased, to about 40° in relation to the GaN substrate Next, the GaN substrate 1 was placed in a MOVPE (Metalorganic Vapour-phase Epitaxy) reactor, where, at temperature of about 1050° C., the lower cladding layer 2 was formed from Ga_{0.92}Al_{0.08}N with a thickness of 800 nm, doped with silicone to a level of 5×10¹⁸ cm⁻³. Next, at the same temperature, the lower waveguide layer 4 was formed from undoped GaN with a thickness of about 100 nm, acting as the lower waveguide. After lowering the temperature to 820° C., a layer constituting the light generating active region 7 was formed, in a form of an In_{0.1}Ga_{0.9}N/In_{0.02}Ga_{0.98}N multi-quantum well, where the number of repetitions of the multi-quantum well was equal to three. Next, after increasing the reactor temperature to a level of 1050° C., the electron blocking layer 6 was formed from Al_{0.2}Ga_{0.98}N:Mg. Next, the upper light guide layer 5 was formed, constituting the undoped GaN layer forming the upper waveguide. The next layer was the upper cladding layer 3 of Al_{0.05}Ga_{0.95}N with a thickness of 430 nm. The structure growth was finished on a thin contact layer 8 made of GaN:Mg with magnesium concentration higher than 10²⁰ cm⁻³. After finishing the structure growth, the reactor was cooled down in nitrogen atmosphere. After the epitaxial growth, as a result of different growth rate of various crystallographic planes, the inclination angles of oblique deflector planes 15a have changed to about 45° in relation to the GaN substrate 1.

Subsequent steps of manufacturing of devices follow traditional methods of semiconductor laser manufacturing.

First, photolithography was carried out, defining the shape of mesas of future lasers in a form of a series of stripes, using the pattern 20, with the longer axis oriented according to the crystallographic direction M. A positive photoresist 18 was used, with a thickness of 2 μm, which, after development, took a shape of stripes. Next, dry etching of the crystal was carried out by means of active Ar and Cl ions, to a depth of 500 nm. Thus, a mesa in the cladding layer 3 and in the subcontact layer 8 was formed. Next, a layer of insulating material 10 was deposited on the entire crystal, made of SiO₂ with a thickness of 200 nm. Due to a high thickness of the photoresist 25, its lateral edges are not entirely covered by the insulator 10. Carrying out lift-off allows exposing the ridge of the mesa, while simultaneously leaving the insulator 10 on the side walls of the mesa and on the area outside the mesa. The next technological step is carrying out another photolithography using the pattern 20, obtaining a series of windows in the photoresist 26 in a shape of stripes and depositing the top electrical contact 9 made of a nickel-gold alloy with a thickness of 100 nm. Next, photolithography was carried out using the pattern 21 using a positive photoresist 27, a 1 μm thick layer of gold was deposited, and a lift-off process was carried out to create the contact fields 13 made of gold to form wire connections to the devices.

Next, a layer of negative photoresist 28 was applied, with a thickness of 5 μm, irradiated according to the pattern 22, and developed. The next step was etching to a depth of 3 μm to form vertical mirrors 14 of the laser diodes and to lower the deflector planes 15a to the target position of the deflector planes 15. After removing the remains of the negative photoresist 28, another photolithography was carried out, defining the positive photoresist 29 covering the deflector planes 15 according to the pattern 23, and then wet etching in a TMAH solution was carried out to smooth the side of the crystal. The etching was carried out at a temperature of 70° C. for 15 minutes. Next, the remains of the photoresist 29 were removed and another positive photoresist layer 30 was applied, defining the areas acting as light deflectors, using the pattern 24. In the next step, they were coated with a dielectric multilayer 16 with a high reflection coefficient. The layers of SiO₂ (silicon oxide) and Ta₂O₅ (tantalum oxide) were deposited alternately (five repeats) using electron-beam vacuum evaporation method, forming a distributed Bragg reflector with a maximum reflection for the wavelength of the quantum well emission. The process was completed by removing the positive photoresist 30 along with the oxide layers deposited on it, in an ultrasonic scrubber.

Geometrical details of the design (height of the oblique plane of the deflectors 15) have been selected such that the entire light beam emitted by the emitter falls on the area of the oblique plane of the deflectors 15 inclined at an angle of 45° in relation to the GaN substrate 1 (no losses due to the light propagation above the plane as shown schematically in FIG. 5c). This condition is satisfied when the geometrical parameters of the two-dimensional laser diode array satisfy the relationship:

$$\frac{{H}_{V} - {H}_{QW} + {D}_{V}}{1 - Tan ( {α}_{1 / 2} )} \cdot Tan ( {α}_{1 / 2} ) + {H}_{V} - {H}_{QW} < 0.95 {H}_{D}$$

where H_{V} is the etching depth of the vertical mirror 14, H_{OW} is the height difference between the top plane of the cladding layer 8 and the surface of the quantum wells, D_{V} is the distance between the vertical mirror 14 and the bottom edge of the oblique plane of the deflectors 15 inclined at an angle of 45° in relation to the GaN substrate 1, and H_{D} is the height of the oblique plane of the deflectors 15 inclined at an angle of 45° in relation to the GaN substrate 1.

Manufacturing of the array was finished by embedding the bottom contact, made of gold, on the bottom side of the GaN substrate 1 and mounting in a hermetic housing on a pad with high thermal conductivity coefficient using an SnPb (tin/lead) solder on the bottom contact side (the smooth surface). The burn-in process at temperature of 200° C. allowed coupling the device permanently to the pad and to the whole housing. Next, using the ball-bonding technique (ball-wedge wire bonding technique), an electrical contact was formed between the contact fields 13 made of gold and the electrical leads of the housing.

### EXAMPLE 2

Another embodiment of the present invention is a two-dimensional laser diode array with a square uniform profile of the generated light, comprising eighteen diodes/emitters, wherein the array may comprise any number of emitters. The array is manufactured following the technological steps described in Example 1, wherein the dimensions and position of the oblique planes 15 (defined during photolithography 19), the laser stripes (defined during photolithography 20), and the edges of the vertical mirror (defined during photolithography 22) have been chosen such that all light beams emitted by the array (the light emitted by both ends of the emitter and reflected by the oblique planes of deflectors 15) are parallel to each other, forming a lattice with a constant distance in the horizontal and vertical directions equal to 1000 μm.

A single emitter of the two-dimensional laser diode array comprises subsequently deposited layers, that is the GaN substrate 1 with a thickness of 200-600 nm, preferably 200-400 nm, and particularly preferably 200-300 nm, a lower cladding layer 2 with n-type electrical conductivity, a lower light guide layer 4 with n-type electrical conductivity, a light-emitting layer 7, an electron blocking layer 6 with p-type electrical conductivity, an upper light guide layer 5, an upper cladding layer 3 with p-type electrical conductivity, and a subcontact layer 8 with p-type electrical conductivity, wherein it comprises etched ridges defining waveguides of the laser diodes and etched vertical mirrors 14 forming the resonant cavity. Each emitter comprises light beam deflectors 15 configured to change the direction of emitted light beams from parallel to perpendicular in relation to the plane defined by the layer constituting the light generating active region 7, wherein the light beam deflectors 15 comprise two planes, namely a parallel deflector plane 17 in relation to the GaN substrate 1 and an oblique deflector plane 15 inclined at an angle of 40°-50°, particularly preferably at an angle of 45° in relation to the surface of the GaN substrate 1, whereas the parallel deflector plane of 17 is located higher than the subcontact layer 8 by at least 0.5 μm.

The array comprises three rows of emitters, six emitters in each row, with a length of a single emitter of 995 μm, the light of which is reflected by oblique deflector planes 15 inclined at an angle of 45° in relation to the GaN substrate 1 with a height of 5 μm, the half of height of which is located preferably at a distance of 2.5-7.5 μm from the vertical mirror 14 of the emitter, so that the distance between the central point of the light beams coming from both ends of a single emitter is equal to 1000 μm. At the same time, the axes of all emitters are parallel to each other, and the distances between the axes of emitters in one row are equal to 1000 μm. The distance between the nearest ends of emitters from adjacent rows and the same column is equal to 1005 μm. Thus, the distances between the central point of the nearest light beams coming from adjacent emitters in the same column and in different rows are equal to 1000 μm.

### EXAMPLE 3

In other variants of the embodiment of the invention, it is possible to choose any spatial arrangement of the light sources of the array, i.e. emitters at distances of 750 to 1250 μm. It is usually technologically advantageous to arrange them to form a rectangular lattice, that is, so the axes of all lasers are parallel to each other, and the vertical and horizontal distances between the closer ends of adjacent lasers take constant values (not necessarily equal vertically and horizontally). A particularly preferred variant is to choose a vertical and a horizontal distance between adjacent lasers, as well as the length of emitters such that they are equal. In this case, all emitted light beams are parallel to each other (both between the adjacent emitters and the ends of the same emitter), which allows an approximately uniform distribution of light intensity across the majority of the array area.

### LIST OF INDICATIONS

1—a substrate in a form of monocrystalline gallium nitride (GaN),
2—a lower cladding layer,
3—an upper cladding layer,
4—a lower light guide layer,
5—an upper light guide layer,
6—electron blocking layers,
7—a layer constituting the light generating active region,
8—a subcontact layer,
9—a top electrical contact,
10—a dielectric layer,
11—an epitaxial structure,
12—a waveguide,
13—a top electrical contact,
14—vertical mirrors,
15—deflectors, an oblique deflector plane in relation to the GaN substrate in the final position,
15a—an oblique deflector plane in relation to the GaN substrate at the initial step of manufacturing,
16—deflector coatings,
17—a parallel deflector plane in relation to the GaN substrate,
18—a photoresist layer,
19—a photolithographic pattern enabling forming the deflectors,
20—a photolithographic pattern enabling forming the laser stripes and the electrical contact,
21—a photolithographic pattern enabling forming the contact fields,
22—a photolithographic pattern enabling vertical etching of the laser diode mirrors,
23—a photolithographic pattern enabling smoothing the vertical mirrors,
24—a photolithographic pattern enabling coating the deflector planes,
25—a developed photoresist layer used to define the shape of the laser ridge,
26—a developed photoresist layer used to define the shape of the top contact,
27—a developed photoresist layer used to define the shape of the contact fields,
28—a negative photoresist defining the vertical etching,
29—a positive photoresist exposing the area of the vertical mirrors,
30—a positive photoresist defining the shape of the areas with the high reflection coefficient coating.

1. A method for manufacturing a two-dimensional laser diode array comprising preparing:
a) a structured gallium nitride bulk substrate,
b) a lower cladding layer with n-type electrical conductivity,
c) a lower light guide layer with n-type electrical conductivity,
d) a light-emitting layer,
e) an electron blocking layer with p-type electrical conductivity,
f) an upper light guide layer,
g) an upper cladding layer with p-type electrical conductivity,
h) a subcontact layer with p-type electrical conductivity,
with etched ridges defining the laser waveguides and etched mirrors constituting the resonant cavity, wherein the method comprises, in step (a), forming light beam deflectors (15) in the bulk GaN substrate (1) with a thickness of at least 200 μm, by applying a positive photoresist layer (18), irradiating with a spatially variable dose of light, developing and then dry etching of the applied layer in order to obtain the light beam deflectors (15), wherein the light beam deflectors (15) comprise two planes, namely a parallel deflector plane (17) in relation to the GaN substrate (1) and an oblique deflector plane (15a) tilted at an angle in range of 40°-50° in relation to the surface of the GaN substrate (1), wherein dry etching is performed before epitaxy of the lower cladding layer (2) with n-type electrical conductivity, and the parallel deflector plane (17) is located higher than the subcontact layer (8) applied in step (h) by at least 0.5 μm.

2. The method according to claim 1 wherein the two-dimensional laser diode array is obtained, satisfying the relation defined by the equation,
$$\frac{{H}_{V} - {H}_{QW} + {D}_{V}}{1 - Tan ( {α}_{1 / 2} )} \cdot Tan ( {α}_{1 / 2} ) + {H}_{V} - {H}_{QW} < 0.95 {H}_{D}$$
wherein,
H_{V} is the etching depth of the vertical mirror (14),
H_{OW} is the height difference between the top plane of the subcontact layer (8) and the quantum well plane,
D_{V} is the distance between the vertical mirror (14) and the bottom edge of the oblique deflector plane (15a), tilted at an angle of 45° in relation to the GaN substrate (1),
H_{D} is the height of the oblique deflector plane (15a), tilted at an angle of 45° in relation to the GaN substrate (1).

3. The method according to claim 1, wherein the dry etching is carried out by means of reactive ion etching method using argon-chlorine plasma.

4. The method according to claim 1, wherein after dry etching of the applied photoresist layer (18), light beam deflectors (15) with an inclination angle of the oblique deflector plane (15a) in relation to the surface of the GaN substrate (1) preferably equal to 40° are obtained.

5. The method according to claim 1, wherein after epitaxial growth of the subcontact layer (8), light beam deflectors (15) with an inclination angle of the oblique deflector plane (15a) in relation to the surface of the GaN substrate (1) preferably equal to 45° are obtained.

6. The method according to claim 1, wherein the parallel deflector plane (17) and oblique deflector plane (15a) are coated with a layer with a high reflection coefficient.

7. The method according to claim 1, wherein the layer with a high reflection coefficient is formed by alternating deposition of SiO₂ and Ta₂O₅ using electron-beam vacuum evaporation method.

8. A two-dimensional laser diode array based on an AlInGaN alloy, manufactured using the method defined in claim 1, comprising sequentially a structured gallium nitride bulk substrate, a lower cladding layer with n-type electrical conductivity, a lower light guide layer with n-type electrical conductivity, a light-emitting layer, an electron blocking layer with p-type electrical conductivity, an upper light guide layer, an upper cladding layer with p-type electrical conductivity, and a subcontact layer with p-type electrical conductivity, with etched ridges defining waveguides of the laser diodes and etched mirrors forming the resonant cavity,
wherein the GaN substrate (1) has a thickness of at least 200 μm, and the laser diodes are arranged in a rectangular lattice, wherein each diode comprises light beam deflectors (15) configured to change the direction of emitted light beams from parallel to perpendicular in relation to the plane defined by the layer constituting the light generating active region (7), wherein the light beam deflectors (15) comprise two planes, namely a parallel deflector plane (17) in relation to the GaN substrate (1) and an oblique deflector plane (15a) tilted at an angle of 40°-50° in relation to the surface of the GaN substrate (1), wherein the parallel deflector plane (17) is located higher than the subcontact layer (8) by at least 0.5 μm.

9. The two-dimensional array according to claim 8, wherein it satisfies the relationship defined by the equation,
$$\frac{{H}_{V} - {H}_{QW} + {D}_{V}}{1 - Tan ( {α}_{1 / 2} )} \cdot Tan ( {α}_{1 / 2} ) + {H}_{V} - {H}_{QW} < 0.95 {H}_{D}$$
wherein,
H_{V} is the etching depth of the vertical mirror (14),
H_{OW} is the height difference between the top plane of the subcontact layer (8) and the quantum well plane,
D_{V} is the distance between the vertical mirror (14) and the bottom edge of the oblique deflector plane (15a), tilted at an angle of 45° in relation to the GaN substrate (1),
H_{D} is the height of the oblique deflector plane (15a), tilted at an angle of 45° in relation to the GaN substrate (1).

10. The two-dimensional array according to claim 8, wherein the oblique deflector planes (15a), after dry etching, are tilted at an angle of 40° in relation to the surface of the GaN substrate (1).

11. The two-dimensional array according to claim 8, wherein the oblique deflector planes (15), after epitaxial growth of the subcontact layer (8), are tilted at an angle of 45° in relation to the surface of the GaN substrate (1).

12. The two-dimensional array according to claim 8, wherein the parallel deflector planes (17) and the oblique deflector planes (15a) are coated with a layer with a high reflection coefficient.

13. The two-dimensional array according to claim 8, wherein the layer with a high reflection coefficient is constituted by a layer of SiO₂ and Ta₂O₅.

14. The two-dimensional array according to claim 8, wherein the distance between parallel planes (17) defined by the centre of the active region and the plane intersecting the deflector (15) in the middle of its height is comprised in range of +/−250 nm.

15. The two-dimensional array according to claim 8, wherein the total thickness of the laser diode array structure measured from the bottom plane of the GaN substrate (1) to the parallel deflector plane (17) is comprised in range of 200 to 800 μm.

16. The two-dimensional array according to claim 8, wherein the distance between the vertical mirror (14) of the laser diode and the intersection of the extension of the waveguide axis of the laser diode with the oblique deflector plane (15a) is comprised in range of 2.5 to 7.5 μm.
